(19) United States
(12) Patent Application Publication
(10) Pub. No.: US 2026/0341374 A1
(43) Pub. Date: Oct. 29, 2026

(54) MEMORY DEVICE INCLUDING PAGE BUFFER AND METHOD FOR OPERATION THEREOF

(71) Applicant: Samsung Electronics Co., Ltd., Suwon-si (KR)

(72) Inventors: Sara CHOI, Suwon-si (KR); Hyunkook PARK, Suwon-si (KR); Ji-Sang LEE, Suwon-si (KR)

(21) Appl. No.: 19/566,703

(22) Filed: Mar. 13, 2026

(30) Foreign Application Priority Data
Apr. 28, 2025 (KR) 10-2025-0055437

(51) Int. Cl. G11C 16/30; G11C 16/26

(52) U.S. Cl. CPC G11C 16/30; G11C 16/26

(57) ABSTRACT

An operating method of a memory device including a memory cell array and a page buffer connected to the memory cell array through a plurality of bitlines may include pre-charging a sensing node of a sensing circuit of the page buffer connected to a first bitline among the plurality of bitlines, setting a trip voltage based on a mode of the page buffer, generating a voltage of a latch input node connected between the sensing circuit and a latch circuit of the page buffer from a voltage of the sensing node based on the trip voltage, and latching a value corresponding to the voltage of the latch input node into the latch circuit.

### CROSS-REFERENCE TO RELATED APPLICATION(S)

This application claims the benefit of Korean Patent Application No. 10-2025-0055437, filed on April 28, 2025, in the Korean Intellectual Property Office, the disclosure of which is incorporated herein by reference in its entirety.

### BACKGROUND

### 1. FIELD OF THE INVENTION

Example embodiments relate to a memory device, more specifically, a memory device including a page buffer, and a method for an operation thereof.

### 2. DESCRIPTION OF THE RELATED ART

A memory device may include a page buffer. A cell array included in the memory device may be accessed in units of pages, and the page buffer may latch a page read from the cell array and/or a page to be written in the cell array. In addition, the page buffer may additionally perform a logic operation between latched data and other data. To reduce power consumption of the memory device, a supply voltage may be reduced, and an operating voltage of the page buffer may also be reduced. Accordingly, it is important for the page buffer to successfully perform various operations despite a reduced operating voltage.

### SUMMARY

An aspect provides a memory device including a page buffer with high credibility for various operations, and an operating method thereof.

According to example embodiments, an operating method of a memory device including a memory cell array and a page buffer connected to the memory cell array through a plurality of bitlines may include pre-charging a sensing node of a sensing circuit of the page buffer connected to a first bitline among the plurality of bitlines, setting a trip voltage based on a mode of the page buffer, generating a voltage of a latch input node connected between the sensing circuit and a latch circuit of the page buffer from a voltage of the sensing node based on the trip voltage, and latching a value corresponding to the voltage of the latch input node into the latch circuit.

According to example embodiments, a memory device may include a memory cell array including a plurality of memory cells, a page buffer connected to the memory cell array through a plurality of bitlines, and a control circuit configured to control the page buffer. The page buffer may include a sensing circuit configured to generate a voltage of a latch input node from a voltage of a sensing node based on a trip voltage, and a latch circuit configured to latch a value corresponding to the voltage of the latch input node. The control circuit may be configured to set the trip voltage based on a mode of the page buffer.

According to example embodiments, an operating method of a memory device including a memory cell array and a page buffer connected to the memory cell array through a plurality of bitlines may include pre-charging a sensing node of a sensing circuit of the page buffer connected to a first bitline among the plurality of bitlines, developing a voltage of the sensing node based on a cell current flowing through the first bitline, setting a first trip voltage, generating a first voltage of a latch input node from the voltage of the sensing node developed based on the first trip voltage, latching a value corresponding to the first voltage into a latch circuit of the page buffer, setting a second trip voltage different from the first trip voltage, generating a second voltage of the latch input node from the voltage of the sensing node developed based on the second trip voltage, and latching a value corresponding to the second voltage into the latch circuit.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is a block diagram illustrating a storage device according to an example embodiment of the present disclosure;

FIG. 2 is a block diagram illustrating a memory device according to an example embodiment of the present disclosure;

FIG. 3 is a schematic diagram illustrating a structure of a memory cell array according to an example embodiment of the present disclosure;

FIG. 4 is a diagram illustrating a memory cell array and a page buffer of a memory device according to an example embodiment of the present disclosure;

FIG. 5 is a block diagram illustrating a page buffer according to an example embodiment of the present disclosure;

FIGS. 6A and 6B are diagrams illustrating examples of trip voltages of a memory device according to example embodiments of the present disclosure;

FIG. 7 is a circuit diagram illustrating a page buffer according to an example embodiment of the present disclosure;

FIG. 8 is a timing diagram illustrating an example of a sensing operation of a page buffer according to an example embodiment of the present disclosure;

FIG. 9 is a timing diagram illustrating an example of a dump operation of a page buffer according to an example embodiment of the present disclosure;

FIG. 10 is a circuit diagram illustrating a page buffer according to an example embodiment of the present disclosure;

FIGS. 11A and 11B are timing diagrams illustrating examples of a multi- sensing operation of a page buffer according to example embodiments of the present disclosure;

FIG. 12 is a circuit diagram illustrating a page buffer according to an example embodiment of the present disclosure;

FIG. 13 is a timing diagram illustrating an example of a multi-sensing operation of a page buffer according to an example embodiment of the present disclosure;

FIG. 14 is a circuit diagram illustrating a page buffer according to an example embodiment of the present disclosure;

FIG. 15 is a flowchart illustrating an operating method of a memory device according to an example embodiment of the present disclosure;

FIG. 16 is a flowchart illustrating a method of a sensing operation of a memory device according to an example embodiment of the present disclosure;

FIG. 17 is a flowchart illustrating a method of a dump operation of a memory device according to an example embodiment of the present disclosure;

FIG. 18 is a flowchart illustrating an operating method of a memory device according to an example embodiment of the present disclosure; and

FIG. 19 is a block diagram illustrating a memory system according to example embodiments of the present disclosure.

### DETAILED DESCRIPTION

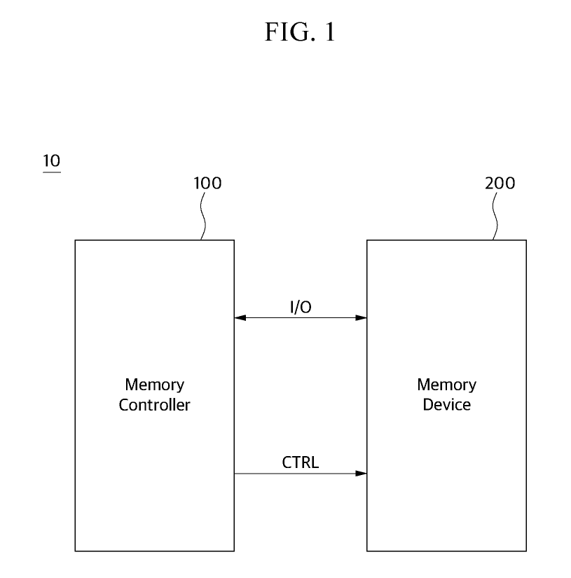

FIG. 1 is a block diagram illustrating a storage device 10 according to an example embodiment of the present disclosure. The storage device 10 may be referred to as a memory system or a storage system, and referring to FIG. 1, may include a memory controller 100 and a memory device 200. In some example embodiments, the memory controller 100 and the memory device 200 may be manufactured through a semiconductor process and included in one package or two separate packages.

The memory controller 100 may communicate with a host (not shown) and the memory device 200 and control data exchange between the host and the memory device 200. For example, the memory controller 100, in response to a request received from the host, may control the memory device 200 to write data to the memory device 200 or to read or erase data stored in the memory device 200. For example, the memory controller 100 may control write, read, and erase operations for the memory device 200 by providing an input/output signal I/O that includes an address and/or a command and a control signal CTRL to the memory device 200. Furthermore, data that is to be written in the memory device 200 and data that is read from the memory device 200 may be transmitted and received between the memory controller 100 and the memory device 200 through a input/output signal I/O. Herein, for convenience of description, the terms of the input/output signal I/O and the input/output signal line I/O may be used interchangeably, and the terms of the control signal CTRL and a control signal line CTRL may be used interchangeably.

The memory device 200 may perform operations, for example, write, read, and erase operations, based on the input/output signal I/O and the control signal CTRL that are received from the memory controller 100. In some example embodiments, the memory device 200 may include a volatile memory device or a non-volatile memory device. Hereinafter, the memory device 200 may be assumed to be a non-volatile memory device, and a flash memory device as the non-volatile memory device will be mainly described, but example embodiments of the present disclosure are not limited thereto.

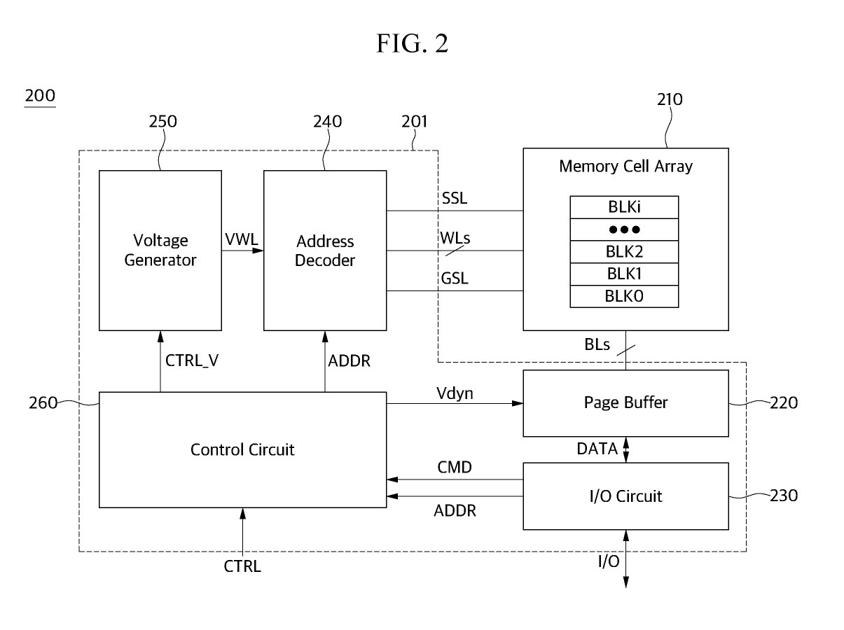

FIG. 2 is a block diagram illustrating the memory device 200 according to an example embodiment of the present disclosure. Referring to FIG. 2, the memory device 200 may include a peripheral circuit 201 and a memory cell array 210, and the peripheral circuit 201 may include a page buffer 220, an input/output (I/O) circuit 230, an address decoder 240, a voltage generator 250, and a control circuit 260. Although not illustrated in FIG. 2, the peripheral circuit 201 may further include various elements related to a memory operation.

The peripheral circuit 201 may receive a command CMD, an address ADDR, and/or data DATA through an input/output signal I/O from the memory controller 100 of FIG. 1 and may write the data DATA to the memory cell array 210 or read the data DATA from the memory cell array 210 to provide the data DATA to the memory controller 100 in response to the command CMD and the control signal CTRL.

The memory cell array 210 may include a plurality of memory cells, and for example, the plurality of memory cells may be flash memory cells. In addition, each of the flash memory cells may include a transistor that has a floating gate or a charge trap layer and save at least one bit corresponding to a threshold voltage of the transistor. In some example embodiments, the memory cell array 210 may include a single level cell (SLC) that stores a single bit or a multi-level cell (MLC) or a triple-level cell (TLC) that store two or more bits. Hereinafter, a case where a plurality of flash memory cells are NAND flash memory cells will be mainly described, but example embodiments of the present disclosure are not limited thereto, and in some example embodiments, the plurality of memory cells may be NOR flash memory cells or resistive memory cells such as resistive RAM (ReRAM), phase change RAM (PRAM), or magnetic RAM (MRAM).

Among the plurality of memory cells included in the memory cell array 210, memory cells that are connected to the same wordline may be referred to as a page. The memory cell array 210 may write or read data in units of pages, and in this case, data corresponding to a page may be referred to as a page data. The memory cell array 210 may be located beside or above the peripheral circuit 201 in terms of layout design, and particularly, a structure in which the memory cell array 210 is located above the peripheral circuit 201 may be referred to as a cell over peripheral (COP) structure.

The page buffer 220 may be in connect with the memory cell array 210 through a plurality of bitlines BLs and may temporarily store data to be written to the memory cell array 210 or data read from the memory cell array 210. The page buffer 220 may exchange the data DATA as a portion of page data with the I/O circuit 230, and the I/O circuit 230 may exchange the data DATA with the memory controller 100 through the input/output signal line I/O.

According to example embodiments of the present disclosure, the page buffer 220 may include a sensing circuit for sensing data that is read from the memory cell array 210 and a latch circuit for storing sensed data. In addition, as described later with reference to the diagrams, the page buffer 220 may perform a sensing operation, such as a verify operation or a read operation, based on the command CMD, for sensing a value of a memory cell connected through a bitline, and may also perform a dump operation for executing a logic operation based on a value stored in the latch circuit. The page buffer 220 may be configured in one of a plurality of modes corresponding to a plurality of operations and may perform an operation corresponding to a configured mode.

The I/O circuit 230 may provide the data DATA received from the memory controller 100 to the page buffer 220 through the input/output signal line I/O, and output the data DATA received from the page buffer 220 to the memory controller 100. In addition, the I/O circuit 230 may provide the command CMD and the address ADDR inputted through the input/output signal line I/O to the control circuit 260.

The address decoder 240 may be connected to the memory cell array 210 through a string selection line SSL, a plurality of wordlines WLs, and a ground selection line GSL. In addition, the address decoder 240 may be inputted a wordline voltage VWL from the voltage generator 250, may select one among the plurality of wordlines WLs by being inputted an address ADDR from the control circuit 260, and activate a selected wordline, and accordingly, memory cells, in other words, a page, connected to the selected wordline may be selected.

Based on a voltage control signal CTRL_V received from the control circuit 260, the voltage generator 250 may generate various voltages as the wordline voltages VWL and provide the wordline voltages VWL to the address decoder 240 to perform program, read, and erase operations on the memory cell array 210. As an example, the voltage generator 250 may generate a program voltage and a pass voltage during a program operation, and generate and provide a read voltage and a read pass voltage to the address decoder 240 during a read operation.

The control circuit 260 may control program, read, and erase operations of the memory device 200 based on the command CMD provided through the I/O circuit 230. For example, the control circuit 260 may decode and identify the command CMD and control other elements of the memory device 200 in response to an identified command. For example, the control circuit 260 may receive a write command, a read command, or an erase command and control other elements to perform a read operation, a write operation, or an erase operation.

In some example embodiments, the control circuit 260 may generate and provide a control voltage Vdyn to the page buffer 220. The page buffer 220 may set a trip voltage corresponding to a mode of the page buffer 220 based on the control voltage Vdyn and perform a sensing operation and a dump operation of the page buffer 220 based on the trip voltage. In addition, as described later with reference to the diagrams, the control circuit 260 may provide a signal to control elements included in the sensing circuit and the latch circuit of the page buffer 220.

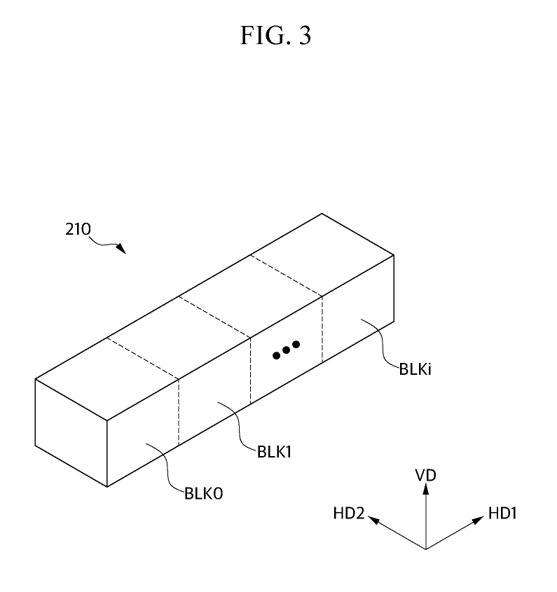

FIG. 3 is a schematic diagram illustrating a structure of the memory cell array 210 according to an example embodiment of the present disclosure. Referring to FIG. 3, the memory cell array 210 may include a plurality of memory blocks BLK0 to BLKi arranged in a first horizontal direction HD1, and in this case, i may be a positive integer.

In some example embodiments, each of the plurality of memory blocks BLK0 to BLKi may have a third dimensional structure and include a plurality of NAND strings extended along a vertical direction VD. In this case, the plurality of NAND strings included in each memory block may be spaced apart by a predetermined distance and arranged along the first horizontal direction HD1 and a second horizontal direction HD2.

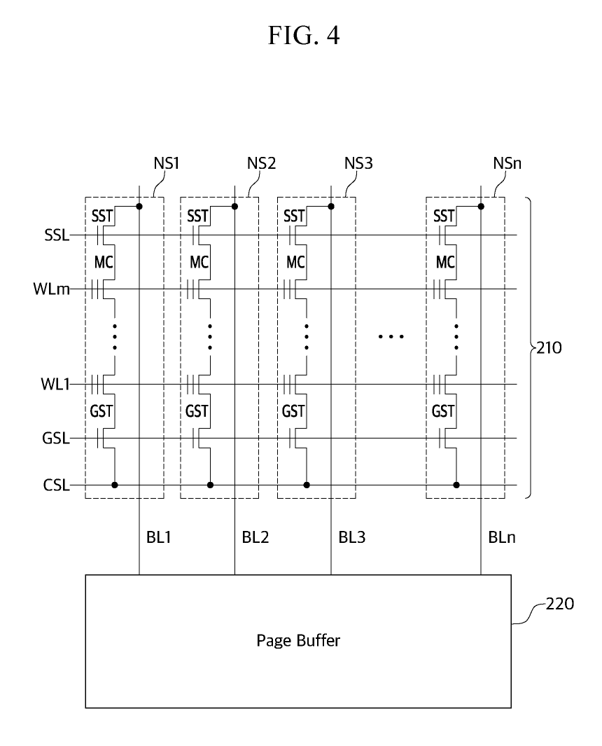

FIG. 4 is a diagram illustrating a memory cell array and a page buffer of a memory device according to an example embodiment of the present disclosure. Referring to FIG. 4, the memory cell array 210 may include first to n NAND strings NS1 to NSn. In addition, each of the first to n NAND strings NS1 to NSn may include a string selection transistor SST connected to the string selection line SSL, a plurality of memory cells MC, each of which is connected to first to m wordlines WL1 to WLm, and a ground selection transistor GST connected to a ground selection line GSL, and the string selection transistor SST, the plurality of memory cells MC, and the ground selection transistor GST may be connected in series. Herein, m and n may be positive integers.

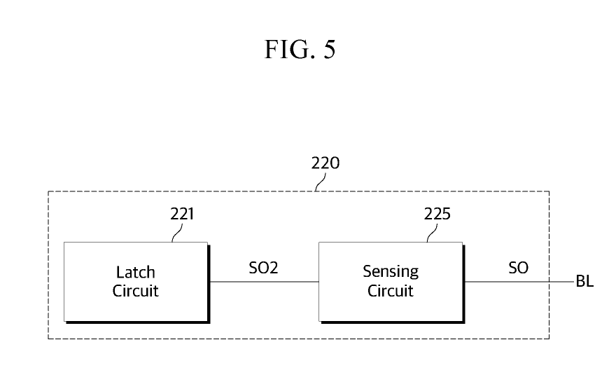

The memory cell array 210 may be connected to the page buffer 220 through first to n bitlines BL1 to BLn, and, for example, as described later with reference to FIG. 5, the memory cell array 210 may be connected to a sensing circuit of the page buffer 220 through a sensing node SO. Although not illustrated in FIG. 4, the page buffer 220 may include a plurality of page buffer units, and each page buffer unit may be connected to one bitline among the first to n bitlines BL1 to BLn. Hereinafter, performing an operation by the page buffer unit may be referred to as performing an operation by the page buffer 220.

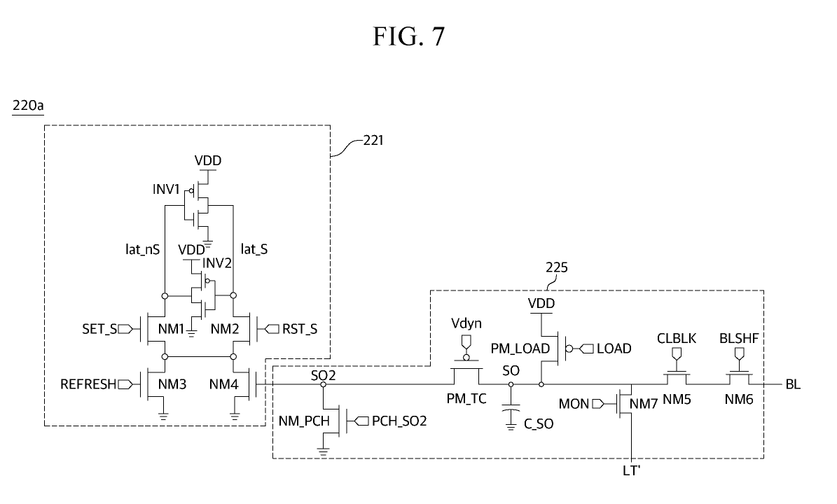

FIG. 5 is a block diagram illustrating the page buffer 220 according to an example embodiment of the present disclosure. Referring to FIG. 5, the page buffer 220 may include a latch circuit 221 and a sensing circuit 225, and the latch circuit 221 may be connected to the sensing circuit 225 through a latch input node SO2, and the sensing circuit 225 may be connected to a bitline BL through a sensing node SO. As described later with reference to FIG. 7, the latch circuit 221 may latch a value corresponding to a voltage of the latch input node SO2, and the sensing circuit 225 may generate the voltage of the latch input node SO2 from a voltage of the sensing node SO in a sensing operation or a dump operation of the page buffer 220 based on a trip voltage of the sensing circuit 225 or the latch circuit 221.

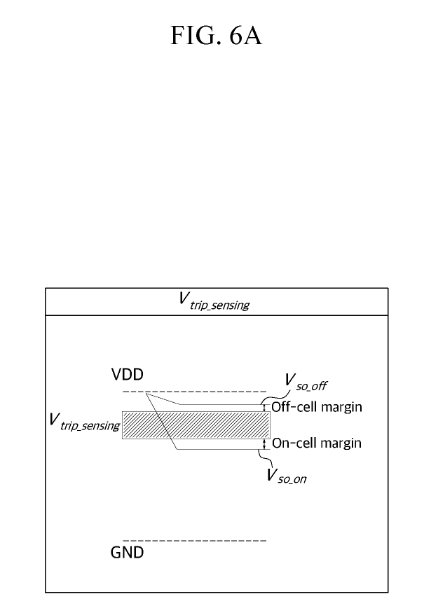

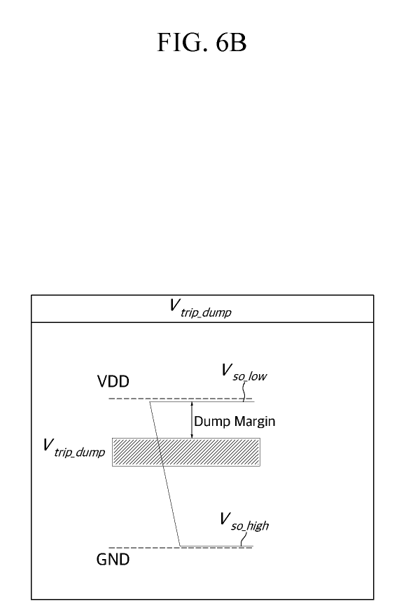

FIGS. 6A and 6B are diagrams illustrating examples of trip voltages of a memory device according to example embodiments of the present disclosure. For example, FIG. 6A may illustrate a sensing trip voltage Vtrip_sensing used in a sensing operation of a page buffer, and FIG. 6B may illustrate a dump trip voltage Vtrip_dump used in a dump operation of the page buffer. Referring to FIGS. 6A and 6B, a trip voltage of the page buffer may be divided into the sensing trip voltage Vtrip_sensing and the dump trip voltage Vtrip_dump depending on a mode of the page buffer, and the sensing trip voltage Vtrip_sensing and the dump trip voltage Vtrip_dump may be represented within a predetermined voltage range, taking variation into account. Hereinafter, FIGS. 6A and 6B will be described with reference to FIG. 5.

The sensing trip voltage Vtrip_sensing may be defined as a reference for determining whether a memory cell is an on-cell or an off-cell. In other words, in a sensing mode of the page buffer 220, the sensing node SO may be developed based on a cell current flowing through the bitline BL, to which a memory cell is connected, after pre-charge, and whether the memory cell is the on-cell or the off-cell is determined based on a comparison between a developed voltage of the sensing node SO and the sensing trip voltage Vtrip_sensing. Referring to FIG. 6A, the developed voltage of the sensing node SO may be higher when the memory cell is the off-cell than when the memory cell is the on-cell (Vso_off > Vso_on), and it is needed to set the sensing trip voltage Vtrip_sensing to an appropriate level to ensure a sufficient on-cell margin and off-cell margin.

Meanwhile, the dump trip voltage Vtrip_dump may be understood as a reference for determining a value (for example, a logic high or a logic low) stored in a latch circuit. Referring to FIG. 6B, during a dump operation period of the page buffer 220, the sensing node SO may maintain a pre-charged voltage when the value stored in the latch circuit is logic low after pre-charge and may be pulled down when the value is logic high. Subsequently, based on a comparison between the voltage of the sensing node SO and the dump trip voltage Vtrip_dump, a voltage of the latch input node SO2 may be generated from the voltage of the sensing node SO, and it is needed to set the dump trip voltage Vtrip_dump to an appropriate level to ensure a sufficient dump margin.

To reduce power consumption of the memory device, supply voltage of the memory device may be reduced, and accordingly, an operating voltage VDD of the page buffer 220 may also decrease. In addition, as the operating voltage VDD of the page buffer 220 decreases, a range of a voltage that may be formed in the sensing node SO may also relatively decrease. Accordingly, if the same level of trip voltage is used in a sensing operation and a dump operation, it may be difficult to ensure a sufficient sensing margin and dump margin at the same time. Hereinafter, referring to the diagrams, example embodiments where a sensing margin and a dump margin are ensured at the same time by setting the trip voltage differently depending on a mode of the page buffer 220 will be described.

FIG. 7 is a circuit diagram illustrating a page buffer 220a according to an example embodiment of the present disclosure. Referring to FIG. 7, the page buffer 220a may include a latch circuit 221 and a sensing circuit 225, and the latch circuit 221 and the sensing circuit 225 may be connected through a latch input node SO2.

The latch circuit 221 may latch a value corresponding to a voltage of the latch input node SO2. The latch circuit 221 may include a first inverter INV1, a second inverter INV2, a first transistor NM1, a second transistor NM2, a third transistor NM3, and a fourth transistor NM4, and the fourth transistor NM4 may have a gate connected to the latch input node SO2. For example, each of the first inverter INV1 and the second inverter INV2 may include a p-channel field effect transistor (PFET) operating as a pull-up transistor and an n-channel field effect transistor (NFET) operating as a pull-down transistor, and an output terminal of the first inverter INV1 and an input terminal of the second inverter INV2 are connected to a latch node lat_S, and an input terminal of the first inverter INV1 and an output terminal of the second inverter INV2 are connected to an inverted latch node lat_nS to form a cross-coupled structure. In addition, the third transistor NM3 may be controlled by a refresh signal REFRESH.

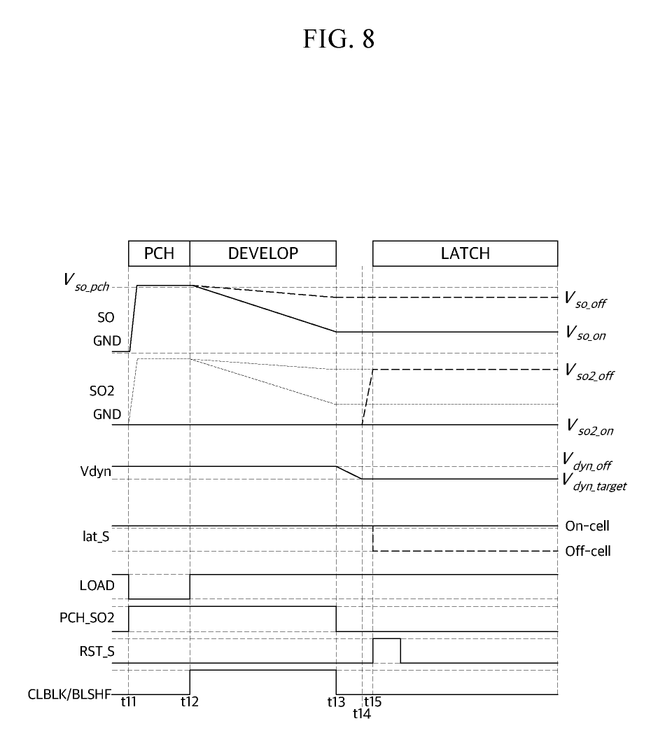

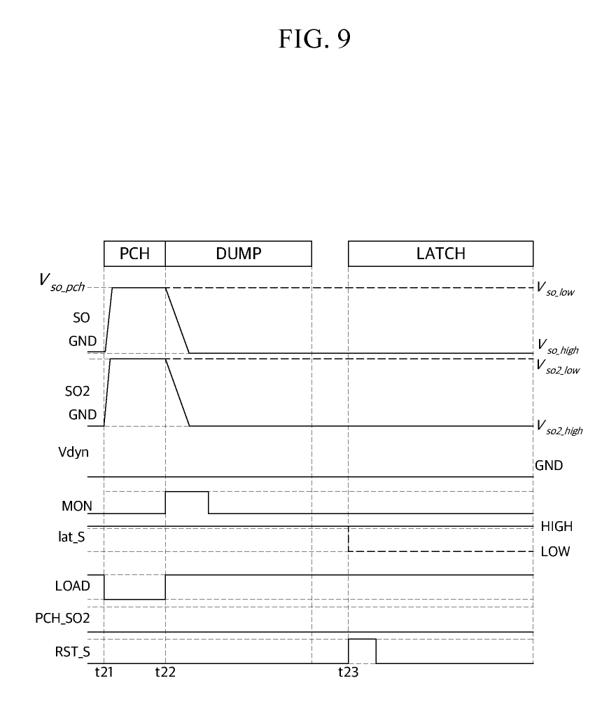

The latch circuit 221 may be tripped in response to a voltage level of the latch input node SO2 at a point when a reset signal RST_S or a set signal SET_S is activated. In other words, a value to be stored in the latch circuit 221 may be determined in response to a voltage level of the latch input node SO2. For example, as described later with reference to FIGS. 8 and 9, when the latch node lat_S is at a high level, and the voltage level of the latch input node SO2 is sufficient to turn on the fourth transistor NM4 at the moment when the reset signal RST_S is activated, the latch node lat_S may be pulled down and inverted to a low level, and when the voltage level of the latch input node SO2 is not sufficient to turn on the fourth transistor NM4, the latch node lat_S may remain at the high level.

The sensing circuit 225 may include a fifth transistor NM5 and a sixth transistor NM6 connected in series between a sensing node SO and a bitline BL, and each of the fifth transistor NM5 and the sixth transistor NM6 may be controlled based on a bitline connection control signal CLBLK and a bitline shut-off signal BLSHF. In addition, the sensing circuit 225 may include a load transistor PM_LOAD and a capacitor C_SO for approximately pre-charging the sensing node SO to an operating voltage VDD and a pre-charge transistor NM_PCH for approximately pre-charging the latch input node SO2 to a ground potential GND. The load transistor PM_LOAD may be controlled by a load signal LOAD, and the pre-charge transistor NM_PCH by a pre-charge control signal PCH_SO2. Furthermore, the sensing circuit 225 may include a seventh transistor NM7 to connect the sensing node SO to another latch LT', for example, a force latch, an upper bit latch, or a lower bit latch, and the seventh transistor NM7 may be turned on in response to a monitoring signal MON to perform a logic operation in a dump mode.

Referring to FIG. 7, a trip control transistor PM_TC included in the sensing circuit 225 may set a trip voltage differently depending on a mode of the page buffer 220a. The control circuit 260 of FIG. 2 may identify a trip voltage corresponding to the mode of the page buffer 220a, apply a control voltage Vdyn to a gate of the trip control transistor PM_TC based on an identified trip voltage, and the trip voltage may be set based on the control voltage Vdyn. For example, the trip voltage may be set to a value obtained by adding an absolute value of a threshold voltage of the trip control transistor PM_TC to the control voltage Vdyn. Accordingly, the control circuit 260 may set the sensing trip voltage Vtrip_sensing and the dump trip voltage Vtrip_dump differently by applying the control voltage Vdyn differently in a sensing mode and a dump mode of the page buffer 220a.

FIG. 8 is a timing diagram illustrating an example of a sensing operation of a page buffer according to an example embodiment of the present disclosure. For example, the timing diagram of FIG. 8 may illustrate a sensing operation of the page buffer 220a illustrated in FIG. 7. Hereinafter, FIG. 8 will be described with reference to FIG. 7.

Referring to FIG. 8, a sensing node SO may be pre-charged at a time t11. For example, as a load signal LOAD is activated at a low level at the time t11, the load transistor PM_LOAD may be turned on, and accordingly, a voltage of the sensing node SO may increase to a pre-charge voltage Vso_pch. In addition, as a pre-charge control signal PCH_SO2 is activated at a high level, the pre-charge transistor NM_PCH may be turned on, and a latch input node SO2 may be pulled down to a ground potential GND. At this point, a control voltage Vdyn supplied to the gate of the trip control transistor PM_TC may be a voltage Vdyn_off to turn off the trip control transistor PM_TC.

At a time t12, the voltage of the sensing node SO may be developed. For example, as the load signal LOAD is inactivated at a high level at the time t12, the load transistor PM_LOAD may be turned off, and as the fifth transistor NM5 and the sixth transistor NM6 are turned on by a bitline connection control signal CLBLK and a bitline shut-off signal BLSHF activated at a high level, the sensing circuit 225 may be connected to the bitline BL. For example, the sensing node SO of the sensing circuit 225 may be electrically connected to the bitline BL when the bitline connection control signal CLBLK and the bitline shut-off signal BLSHF are activated at the high level. At this point, a cell current flowing through the bitline BL may be different depending on a state of a memory cell connected to the bitline BL, in other words, depending on whether the memory cell is an on-cell or an off-cell, and accordingly, the voltage of the sensing node SO may be differently developed as illustrated in FIG. 8.

For example, the voltage of the sensing node SO, in the case of the off-cell, may change from the pre-charge voltage Vso_pch to an off-cell voltage Vso_off, and in the case of the on-cell, change from the pre-charge voltage Vso_pch to an on-cell voltage Vso_on, and as illustrated in FIG. 8, the off-cell voltage Vso_off may have a higher level than the on-cell voltage Vso_on (Vso_off > Vso_on).

At a timet13, as the pre-charge control signal PCH_SO2 is inactivated at a low level, the pre-charge transistor NM_PCH may be turned off, and a pull-down path of the latch input node SO2 may be blocked. At the time t13, the control voltage Vdyn may decrease, and at a time t14, the control voltage Vdyn may change into a target voltage Vdyn_target.

At the time t14, the control voltage Vdyn may reach the target voltage Vdyn_target. The sensing trip voltage Vtrip_sensing may depend on the target voltage Vdyn_target, and a voltage Vso2 of the latch input node SO2 may be generated from a developed voltage of the sensing node SO based on the sensing trip voltage Vtrip_sensing. For example, when the sensing trip voltage Vtrip_sensing is lower than the off-cell voltage Vso_off and higher than the on-cell voltage Vso_on, as illustrated in FIG. 8, the voltage Vso2 of the latch input node SO2 may increase as the trip control transistor PM_TC is turned on only when the developed voltage of the sensing node SO is the off-cell voltage Vso_off, and as illustrated in FIG. 8, a voltage Vso2_off of the latch input node SO2 may increase to the off-cell voltage Vso_off. At this point, the sensing trip voltage Vtrip_sensing may correspond to a value obtained by adding the absolute value of the threshold voltage of the trip control transistor PM_TC to the target voltage Vdyn_target supplied to the trip control transistor PM_TC. When the developed voltage of the sensing node SO is the on-cell voltage Vso_on, the trip control transistor PM_TC is still turned off, and the voltage Vso2_on of the latch input node SO2 may maintain the ground potential GND.

At a time t15, a value corresponding to the voltage Vso2 of the latch input node SO2 may be latched into the latch circuit 221. For example, at the time t15, a reset signal RST_S may be activated, and accordingly, a latch node lat_S may be tripped. At this point, data to be stored in the latch circuit 221 may be determined based on the voltage Vso2 of the latch input node SO2, and referring to FIG. 8, when the latch node lat_S is at a high level, the latch node lat_S may be inverted to a low level if a sensed memory cell is the off-cell, and the latch node lat_S may remain at a high level if the sensed memory cell is the on-cell.

FIG. 9 is a timing diagram illustrating an example of a dump operation of a page buffer according to an example embodiment of the present disclosure. For example, the timing diagram of FIG. 9 may illustrate a dump operation of the page buffer 220a illustrated in FIG. 7. Hereinafter, FIG. 9 will be described with reference to FIG. 7, and redundant details already provided in the descriptions of FIG. 8 will be omitted.

Referring to FIG. 9, as a load signal LOAD is activated at a low level at a timet21, a voltage of a sensing node SO may increase to a pre-charge voltage Vso_pch. Meanwhile, unlike what is described with reference to FIG. 8, a control voltage Vdyn may be a voltage, for example, a ground potential GND, to turn on the trip control transistor PM_TC, and accordingly, the dump trip voltage Vtrip_dump may be set to a level lower than the sensing trip voltage Vtrip_sensing, for example, to the absolute value of the threshold voltage of the trip control transistor PM_TC. In addition, a pre-charge control signal PCH_SO2 may also be inactivated at a low level, unlike in FIG. 8.

In one embodiment, at a time t22, a logic operation based on a value stored in the latch circuit 221 may be performed. For example, as a monitoring signal MON is activated at the time t22, the logic operation based on the value stored in the latch circuit 221 may be performed, and accordingly, a voltage level of the sensing node SO and a voltage level of the latch input node SO2 may change or may be maintained. For example, when the value stored in the latch circuit 221 is logic low, the voltage of the sensing node SO and a voltage of the latch input node SO2 may be the pre-charged voltage Vso_pch, and when the value stored in the latch circuit 221 is logic high, the sensing node SO and the latch input node SO2 may be pull down. In this case, although not shown, the page buffer 220a may include a PFET and an NFET connected between the latch circuit 221 and the sensing circuit 225. For example, a gate of each of the PFET and NFET may be connected to the latch node lat_S, a source of the PFET may be applied with a pre-charge voltage, a source of the NFET may be applied with a ground voltage, and a drain of each of the PFET and NFET may be connected to the sensing node SO.

At a time t23, a value corresponding to a voltage Vso2 of the latch input node SO2 may be latched into the latch circuit 221. For example, as a reset signal RST_S is activated at the time t23, a latch node lat_S may be tripped by the dump trip voltage Vtrip_dump, and when the voltage Vso2 of the latch input node SO2 is at a high level, the latch node lat_S may be a low level, and when the voltage Vso2 of the latch input node SO2 is at a low level, the latch node lat_S may be a high level.

In one embodiment, at a time t22, a logic operation based on a value stored in the another latch LT’ may be performed. For example, as a monitoring signal MON is activated at the timet22, the logic operation based on the value stored in the another latch LT’ may be performed, and accordingly, a voltage level of the sensing node SO and a voltage level of the latch input node SO2 may change or may be maintained. For example, when the value stored in the another latch LT’ is logic high, the voltage of the sensing node SO and a voltage of the latch input node SO2 may be the pre-charged voltage Vso_pch, and when the value stored in the another latch LT’ is logic low, the sensing node SO and the latch input node SO2 may be pull down.

In this case, at a time t23, a value corresponding to a voltage Vso2 of the latch input node SO2 may be latched into the latch circuit 221. For example, as a reset signal RST_S is activated at the time t23, a latch node lat_S may be tripped by the dump trip voltage Vtrip_dump, and when the latch node lat_S is at a high level, and the value stored in the another latch LT’ is logic high, the latch node lat_S may be inverted to a low level, and when the value stored in the another latch LT’ is logic low, the latch node lat_S may maintain a high level.

As described above with reference to FIGS. 8 and 9, as the control voltage Vdyn supplied to the trip control transistor PM_TC is controlled, different trip voltages may be set in the sensing mode and the dump mode. In some example embodiments, the sensing mode may include a verify mode and a read mode, and different trip voltages may be set in the verify mode and the read mode. For example, it is understood that various trip voltages, not limited to the aforementioned example embodiments, may be set based on various modes of a page buffer.

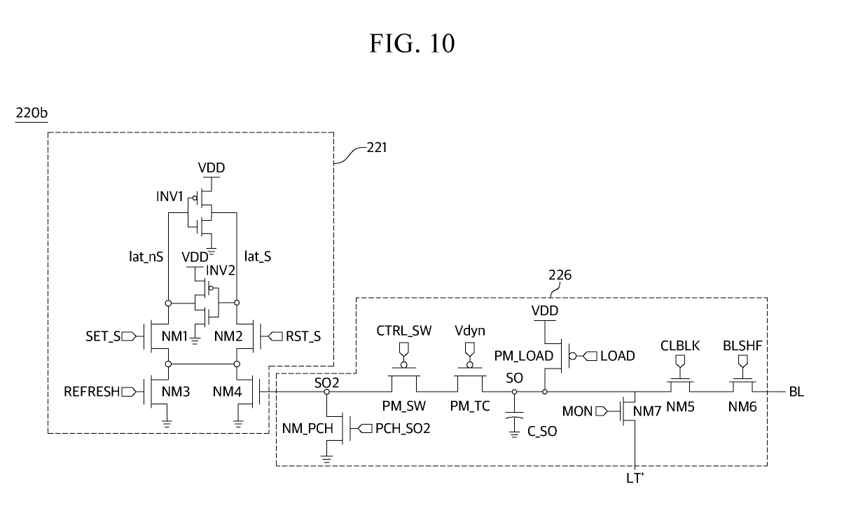

FIG. 10 is a circuit diagram illustrating a page buffer 220b according to an example embodiment of the present disclosure. When comparing to the page buffer 220a illustrated in FIG. 7, the page buffer 220b of FIG. 10 may include a sensing circuit 226 further including a switch transistor PM_SW. The switch transistor PM_SW is illustrated to be located between a trip control transistor PM_TC and a latch input node SO2, but example embodiments of the present disclosure is not limited thereto, and for example, the switch transistor PM_SW may be located between the trip control transistor PM_TC and a sensing node SO. As illustrated in FIG. 10, the switch transistor PM_SW may be controlled by a switch control signal CTRL_SW. Hereinafter, redundant details already provided in the descriptions of FIG. 7 will be omitted from the descriptions of FIG. 10.

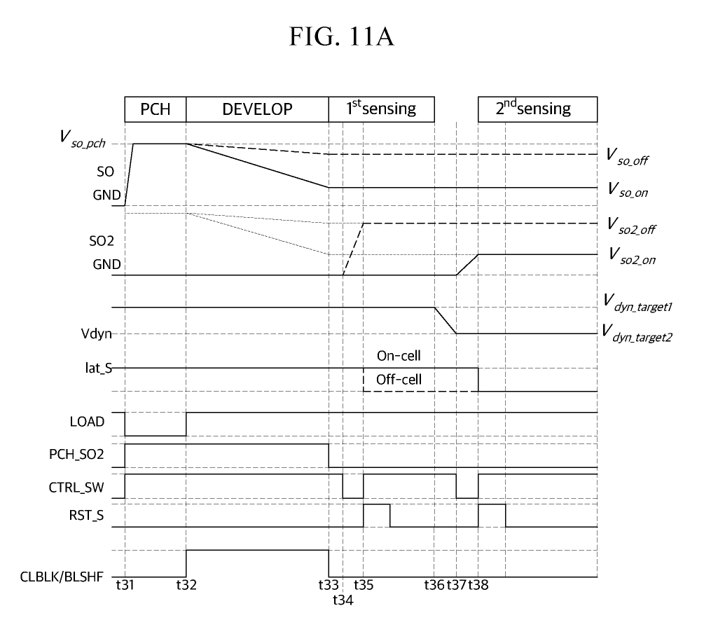

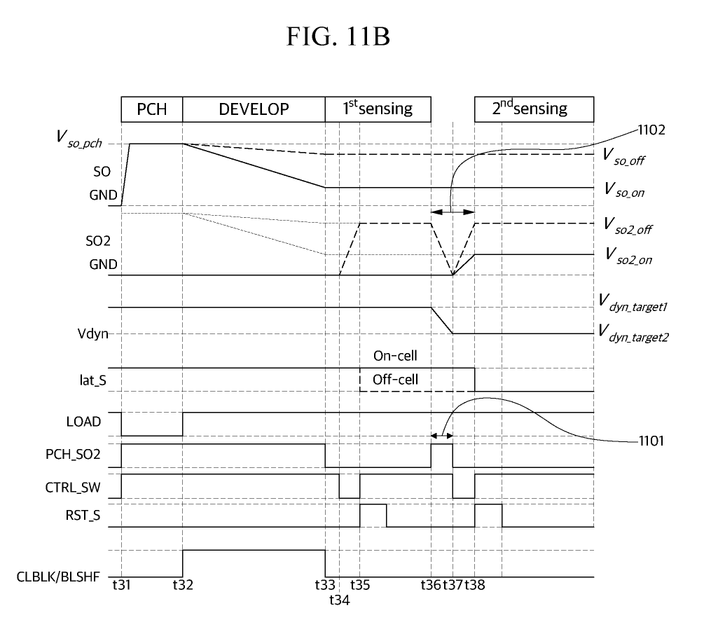

The switch transistor PM_SW may be connected in series with the trip control transistor PM_TC, and as described later with reference to FIGS. 11A and 11B, may be turned off by the switch control signal CTRL_SW in a sensing mode of the page buffer 220b while the sensing node SO is pre-charged and developed. In a dump mode of the page buffer 220b, the switch transistor PM_SW may be turned on by the switch control signal CTRL_SW.

FIGS. 11A and 11B are timing diagrams illustrating examples of a multi-sensing operation of a page buffer according to example embodiments of the present disclosure. For example, the timing diagrams of FIGS. 11A and 11B may illustrate the multi-sensing operation of the page buffer 220b illustrated in FIG. 10. As described later, after developing the sensing node SO one time in the multi-sensing operation, the page buffer 220b may perform multi-sensing by differently setting trip voltages, each of which corresponds to a series of sensing operations. Hereinafter, FIGS. 11A and 11B will be described with reference to FIG. 10, and redundant details already provided in the descriptions of FIG. 8 will be omitted from the descriptions of FIGS. 11A and 11B. In addition, overlapping descriptions between FIGS. 11A and 11B will be omitted.

Referring to FIG. 11A, as a load signal LOAD is activated at a low level at a time t31, a voltage of a sensing node SO may increase to a pre-charge voltage Vso_pch. In addition, a pre-charge control signal PCH_SO2 is activated at a high level to pull down a latch input node SO2, and a control voltage Vdyn may be a first target voltage Vdyn_target1 to perform a first sensing. Accordingly, the sensing trip voltage Vtrip_sensing may be set to a value obtained by adding an absolute value of a threshold voltage of the trip control transistor PM_TC to a first target voltage Vdyn_target1. Meanwhile, a switch control signal CTRL_SW is inactivated at a high level to turn off the switch transistor PM_SW.

At a time t32, the voltage of the sensing node SO may be developed. For example, as the load signal LOAD is inactivated at a high level, and as a bitline connection control signal CLBLK and a bitline shut-off signal BLSHF are activated at the time t32, the sensing circuit 226 may be connected to a bitline BL. At this point, depending on a state of a memory cell connected to the bitline BL, in other words, depending on whether the memory cell is an on-cell or an off-cell, a cell current flowing through the bitline BL may be different, and the voltage of the sensing node SO may change into an off-cell voltage Vso_off during an off-cell sensing and into an on-cell voltage Vso_on during an on-cell sensing.

At a time t33, as the pre-charge control signal PCH_SO2 is inactivated at a low level, a first sensing operation may start. Subsequently, as the switch control signal CTRL_SW is activated at a low level from a time t34 to a time t35, the switch transistor PM_SW may be turned on. Accordingly, a voltage Vso2 of the latch input node SO2 may be generated from a developed voltage of the sensing node SO based on the sensing trip voltage Vtrip_sensing. For example, when the sensing trip voltage Vtrip_sensing is lower than the off-cell voltage Vso_off and higher than the on-cell voltage Vso_on, the trip control transistor PM_TC may be turned on to increase the voltage Vso2 of the latch input node SO2 only when the developed voltage of the sensing node SO is the off-cell voltage Vso_off. In addition, when the developed voltage of the sensing node SO is the on-cell voltage Vso_on, the trip control transistor PM_TC may be turned off, and a voltage Vso2_on of the latch input node SO2 may maintain a ground potential GND.

At the time t35, a value corresponding to the voltage Vso2 of the latch input node SO2 may be latched into the latch circuit 221. For example, at the time t35, a reset signal RST_S may be activated at a high level, and accordingly, a latch node lat_S may be tripped to determine a value to be stored in the latch circuit 221. Referring to FIG. 11A, when the latch node lat_S is at a high level, the latch node lat_S may be inverted to a low level when a sensed memory cell is the off-cell, and when the sensed memory cell is the on-cell, the latch node lat_S may remain at a high level.

At a time t36, the control voltage Vdyn supplied to the trip control transistor PM_TC may change from the first target voltage Vdyn_target1 to a second target voltage Vdyn_target2. At this point, the sensing trip voltage Vtrip_sensing may be set to a value obtained by adding the absolute value of the threshold voltage of the trip control transistor PM_TC to the second target voltage Vdyn_target2, and the value may be at a lower level than the sensing trip voltage Vtrip_sensing in the first sensing operation.

Subsequently, as the switch control signal CTRL_SW is activated at a low level from a time t37 to a time t38, the switch transistor PM_SW may be turned on. Accordingly, the voltage Vso2 of the latch input node SO2 may be generated from the developed voltage of the sensing node SO based on the sensing trip voltage Vtrip_sensing. For example, when the sensing trip voltage Vtrip_sensing is lower than the on-cell voltage Vso_on during a second sensing operation, the trip control transistor PM_TC may be turned on, and the voltage Vso2 of the latch input node SO2 may increase to, for example, the on-cell voltage Vso_on, even when the developed voltage of the sensing node SO is the on-cell voltage Vso_on.

At the time t38, a value corresponding to the voltage Vso2 of the latch input node SO2 may be latched into the latch circuit 221. Referring to FIG. 11A, unlike at the time t35, it is identified that the latch node lat_S is set to a low level regardless of a state of a sensed memory cell at the time t38, and it may be understood that this is because the voltage Vso2 of the latch input node SO2 increases as the sensing trip voltage Vtrip_sensing is set lower when the second sensing operation is performed than when the first sensing operation is performed.

Although an example embodiment in which two sensing operations are performed after a single development of the sensing node SO is illustrated in FIG. 11A, example embodiments of the present disclosure are not limited thereto, and, for example, a random number of different sensing trip voltages Vtrip_sensing may be set to perform a random number of sensing operations. In addition, although the first target voltage Vdyn_target1 is illustrated to have higher voltage level than the second target voltage Vdyn_target2 in FIG. 11A, in various example embodiments, target voltages for performing a multi-sensing operation may be supplied in various manners. For example, target voltages may be set to sequentially increase or decrease over time and may be adjusted by changing the direction of increase or decrease at each sensing.

Referring to FIG. 11B, the timing diagram of FIG. 11B may be understood to illustrate practically identical to FIG. 11A except for first and second sections 1101 and 1102. In example embodiments according to FIG. 11B, a pre-charge control signal PCH_SO2 may be understood to be activated before each sensing. For example, unlike in FIG. 11A, the pre-charge control signal PCH_SO2 may be activated at a time t36 and a time t37, for example, even in the first section 1101. Accordingly, a voltage Vso2_off of a latch input node SO2 during an off-cell sensing may decrease to ground potential GND and then increase back to a voltage level before the time t36 as a switch control signal CTRL_SW is activated at a low level from the time t36 to t38, for example, the second section 1102. Pre-charge may occur more in an example of FIG. 11B than in an example of FIG. 11A.

As described above with reference to FIGS. 11A and 11B, the page buffer 220b may perform a multi-sensing by tripping the latch circuit 221 multiple times as changing a trip voltage after developing the sensing node SO one time. As performing sensing after the development ends, the operating method of the page buffer 220b may decrease power noise compared to concurrent sensing, and in addition, by performing multi-sensing with only one-time sensing node pre-charge and development, an operation that drives a wordline at various voltages may be omitted, which in turn reduces read time.

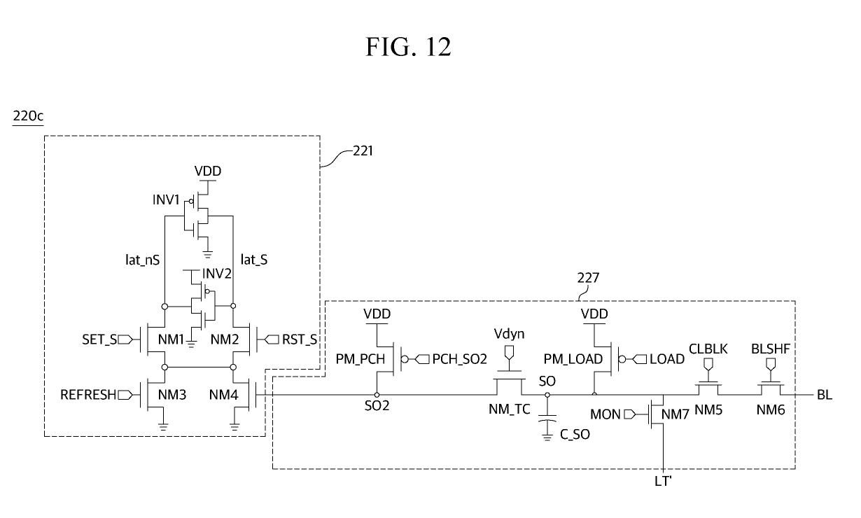

FIG. 12 is a circuit diagram illustrating a page buffer 220c according to an example embodiment of the present disclosure. When compared to the page buffer 220a illustrated in FIG. 7, the page buffer 220c of FIG. 12 may include a trip control transistor NM_TC, which is an NFET, and a pre-charge transistor PM_PCH, which is a PFET. The pre-charge transistor PM_PCH may pull up the latch input node SO2 to approximately an operating voltage VDD in response to a pre-charge control signal PCH_SO2. Hereinafter, redundant details already provided in the descriptions of FIG. 7 will be omitted.

The page buffer 220c of FIG. 12 may have a different trip condition from that of the page buffer 220a of FIG. 7 due to a difference in characteristics of PFET and NFET. For example, in the page buffer 220a of FIG. 7, a trip voltage Vtrip may correspond to a sum of the control voltage Vdyn and the absolute value of the threshold voltage of the trip control transistor PM_TC, and meanwhile, in the page buffer 220c of FIG. 12, the trip voltage Vtrip may correspond to a difference between a control voltage Vdyn and a threshold voltage of the trip control transistor NM_TC. In addition, in the page buffer 220a of FIG. 7, the trip control transistor PM_TC may be turned on only when the voltage Vso of the sensing node SO exceeds the trip voltage Vtrip, and meanwhile, in the page buffer 220c of FIG. 12, the trip control transistor NM_TC may be turned on only when a voltage Vso of a sensing node SO is lower than the trip voltage Vtrip.

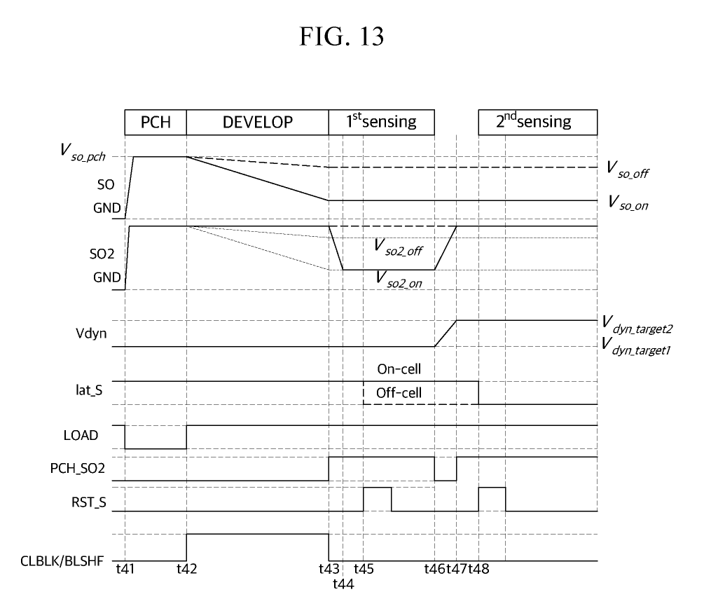

FIG. 13 is a timing diagram illustrating an example of a multi-sensing of a page buffer according to an example embodiment of the present disclosure. For example, the timing diagram of FIG. 13 may illustrate a multi-sensing operation performed in the page buffer 220c of FIG. 12. Hereinafter, FIG. 13 will be described with reference to FIG. 12, and redundant details already provided in the descriptions of FIGS. 11A and 11B will be omitted from the descriptions of FIG. 13.

Referring to FIG. 13, as a load signal LOAD is activated at a low level at a time t41, a voltage Vso of a sensing node SO may increase to a pre-charge voltage Vso_pch. A pre-charge control signal PCH_SO2 may be activated at a low level to pull up a latch input node SO2, and a first target voltage Vdyn_target 1 may be applied to perform a first sensing to a gate of the trip control transistor NM_TC.

At a time t42, the voltage Vso of the sensing node SO may be developed. For example, as the load signal LOAD is inactivated at a high level, and a bitline connection control signal CLBLK and a bitline shut-off signal BLSHF are activated at the time t42, the sensing circuit 227 may be connected to a bitline BL. At this point, the voltage Vso of the sensing node SO may change into an off-cell voltage Vso_off during an off-cell sensing and into an on-cell voltage Vso_on during an on-cell sensing.

At a time t43, the pre-charge control signal PCH_SO2 is inactivated at a high level, and as a voltage Vso2 of the latch input node SO2 is generated based on a comparison between the sensing trip voltage Vtrip_sensing and the voltage Vso of the sensing node SO, the first sensing operation may start. Referring to FIG. 13, when the voltage Vso of the sensing node SO is the off-cell voltage Vso_off, the voltage Vso2 of the latch input node SO2 may maintain a pre-charged voltage level as the trip control transistor NM_TC is turned off, and when the voltage Vso of the sensing node SO is the on-cell voltage Vso_on, the voltage Vso2 of the latch input node SO2 may decrease from the time t43 to a time t44 as the trip control transistor NM_TC is turned on. As an example, the voltage Vso2 of the latch input node SO2 may decrease to the on-cell voltage Vso_on.

At a time t45, a value corresponding to the voltage Vso2 of the latch input node SO2 may be latched into the latch circuit 221. For example, at the time t45, a reset signal RST_S may be activated, and accordingly, as a latch node lat_S is tripped, a value to be stored in the latch circuit 221 may be determined. Referring to FIG. 13, when the latch node lat_S is at a high level, and a sensed memory cell is an off-cell, the latch node lat_S may be inverted to a low level, and when the sensed memory cell is an on-cell, the latch node lat_S may remain at a high level.

At a time t46, a control voltage Vdyn supplied to the trip control transistor NM_TC may change from the first target voltage Vdyn_target1 to a second target voltage Vdyn_target2. Accordingly, the sensing trip voltage Vtrip_sensing during a second sensing operation may be set to a higher level than the sensing trip voltage Vtrip_sensing during the first sensing operation. In addition, from the time t46 to a time t47, as the pre-charge control signal PCH_SO2 is activated, the latch input node SO2 may be pre-charged.

At a timet48, a value corresponding to the voltage Vso2 of the latch input node SO2 may be latched into the latch circuit 221. Referring to FIG. 13, unlike the time t45, it may be identified that the latch node lat_S is set to a low level regardless of whether the sensed memory cell is the on-cell or the off-cell at the time t48.

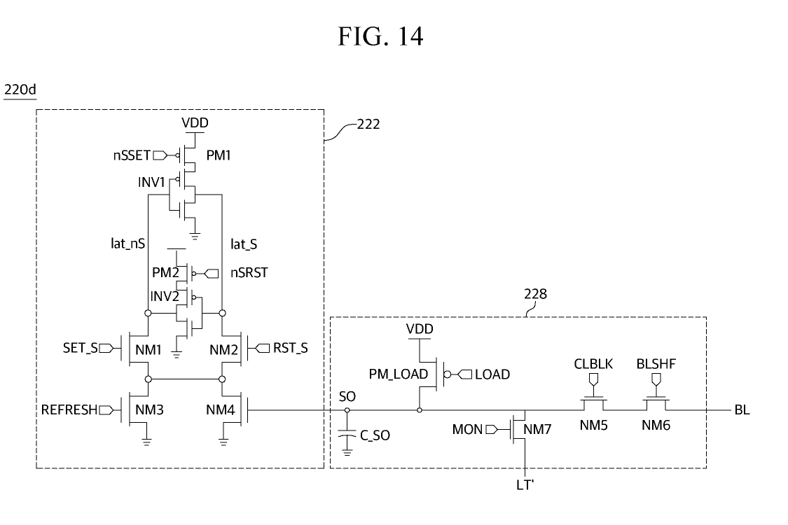

FIG. 14 is a circuit diagram illustrating a page buffer 220d according to an example embodiment of the present disclosure. When comparing to the page buffer 220a illustrated in FIG. 7, in the page buffer 220d illustrated in FIG. 14, a latch circuit 222 may further include first and second PFETs PM1 and PM2 to selectively supply power to first and second inverters INV1 and INV2, and in a sensing circuit 228, a trip control transistor PM_TC may be omitted. Accordingly, in the page buffer 220d of FIG. 14, a sensing node SO may be the same as a latch input node SO2. Hereinafter, redundant details already provided in the descriptions of FIG. 7 will be omitted.

In an example embodiment according to FIG. 14, the first and second PFETs PM1 and PM2 included in the latch circuit 222 may provide an operating voltage VDD to the first and second inverters INV1 and INV2, or block the operating voltage VDD, in response to a corresponding first and second power supply signals nSSET and nSRST, and depending on whether the operating voltage VDD is supplied to the first and second inverters INV1 and INV2, a trip voltage of the latch circuit 222 may be set differently. For example, when the operating voltage VDD is provided to each pull-up transistor of the first and second inverters INV1 and INV2 as the first and second power supply signals nSSET and nSRST are activated, the trip voltage of the latch circuit 222 may be set higher than when the operating voltage VDD is blocked at each of the pull-up transistor of the first and second inverters INV1 and INV2 as the first and second power supply signals nSSET and nSRST are inactivated. Accordingly, in an example embodiment of FIG. 14, the control circuit 260 of FIG. 2 may set the trip voltage differently depending on a mode of the page buffer 220d by activating the first and second power supply signals nSSET and nSRST during a sensing operation of the page buffer 220d and inactivating the first and second power supply signals nSSET and nSRST during a dump operation of the page buffer 220d.

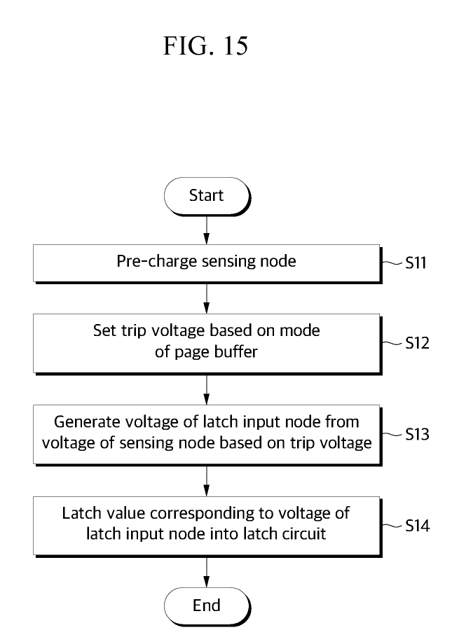

FIG. 15 is a flowchart illustrating an operating method of a memory device according to an example embodiment of the present disclosure. In some example embodiments, the method of FIG. 15 may be performed by the page buffer 220a of FIG. 7. As illustrated in FIG. 15, the operating method of the memory device may include a plurality of operations S11 to S14. Hereinafter, FIG. 15 will be described with reference to FIGS. 7 to 9.

Referring to FIG. 15, a sensing node may be pre-charged in operation S11. For example, as the load signal LOAD is activated, the load transistor PM_LOAD may be turned on, and accordingly, a voltage Vso of the sensing node SO may increase to the pre-charge voltage Vso_pch.

In operation S12, a trip voltage may be set based on a mode of the page buffer 220a. As described above with reference to FIGS. 8 and 9, the page buffer 220a may perform the sensing operation and the dump operation, and different trip voltages corresponding to each operation may be set. For example, the control circuit 260 of FIG. 2 may set the sensing trip voltage Vtrip_sensing and the dump trip voltage Vtrip_dump differently by applying different control voltages Vdyn to the gate of the trip control transistor PM_TC during the sensing operation and the dump operation.

In operation S13, a voltage Vso2 of the latch input node SO2 may be generated from the voltage Vso of the sensing node SO based on the trip voltage. For example, during the sensing operation, the voltage Vso2 of the latch input node SO2 may be generated from the developed voltage of the sensing node SO. For example, when the sensing trip voltage Vtrip_sensing is set to be lower than the off-cell voltage Vso_off and higher than the on-cell voltage Vso_on, the voltage Vso2_off of the latch input node SO2 may increase as the trip control transistor PM_TC is turned on when the developed voltage of the sensing node SO is the off-cell voltage Vso_off, and when the developed voltage of the sensing node SO is the on-cell voltage Vso_on, the voltage Vso2_on of the latch input node SO2 may maintain the ground potential GND as the trip control transistor PM_TC is turned off. Meanwhile, during the dump operation, the voltage Vso2 of the latch input node SO2 may be generated based on a comparison between the dump trip voltage Vtrip_dump and the voltage Vso of the sensing node SO.

In operation S14, a value corresponding to the voltage Vso2 of the latch input node SO2 may be latched into the latch circuit 221. For example, during the sensing operation, a value corresponding to the voltage Vso2 of the latch input node SO2 may be latched into the latch circuit 221 at the time t15 as illustrated in FIG. 8, and during the dump operation, a value corresponding to the voltage Vso2 of the latch input node SO2 may be latched into the latch circuit 221 at the time t23 as illustrated in FIG. 9.

An example embodiment in which the method of FIG. 15 is performed by the page buffer 220a of FIG. 7 is described above, but example embodiments of the present disclosure are not limited thereto, and for example, the method of FIG. 15 may also be performed by the page buffers 220b, 220c, and 220d illustrated in FIGS. 10, 12 and 14. For example, in the page buffer 220d illustrated in FIG. 14, the sensing trip voltage Vtrip_sensing and the dump trip voltage Vtrip_dump may be set differently by changing whether to supply power to an inverter pair included in the latch circuit 222 during the sensing operation and the dump operation in the operation S12.

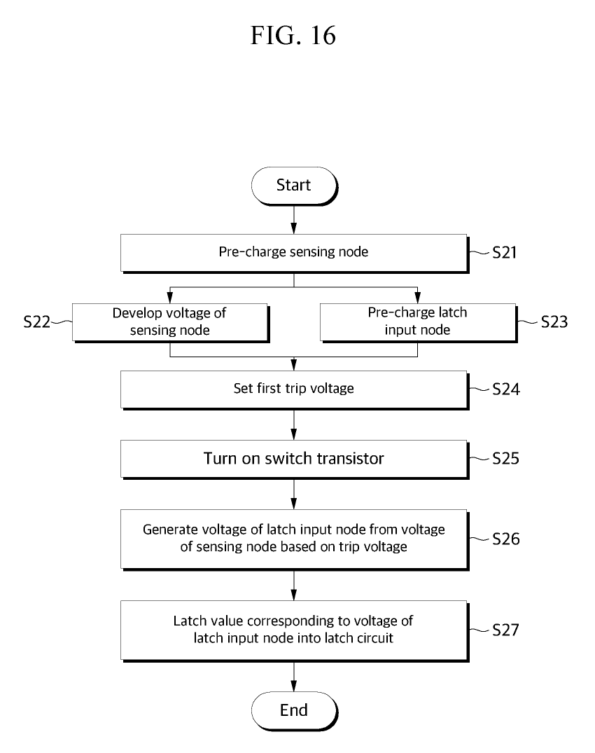

FIG. 16 is a flowchart illustrating a method of a sensing operation of a memory device according to an example embodiment of the present disclosure. In some example embodiments, the method of FIG. 16 may be performed by the page buffer 220b of FIG. 10. As illustrated in FIG. 16, an operating method of the memory device may include a plurality of operations S21 to S27, and operation S22 may be performed in parallel with operation S23. Hereinafter, FIG. 16 will be described with reference to FIGS. 10 and 11A, and redundant details already provided in the descriptions of FIG. 15 will be omitted.

Referring to FIG. 16, the sensing node SO may be pre-charged in operation S21, and a voltage Vso of the sensing node SO may be developed in operation S22. At this point, a cell current flowing through the bitline BL may be different depending on whether the memory cell connected to the bitline BL is the on-cell or the off-cell, and the voltage Vso of the sensing node SO may be differently developed. For example, referring to FIG. 11A, a developed voltage of the sensing node SO when the memory cell is the off-cell, in other words, the off-cell voltage Vso_off, may be higher than a voltage of the sensing node SO when the memory cell is the on-cell, in other words, the on-cell voltage Vso_on.

In operation S23, the latch input node SO2 may be pre-charged. For example, as the pre-charge control signal PCH_SO2 is activated, the pre-charge transistor NM_PCH may be turned on, and the latch input node SO2 may be pulled down to the ground potential GND.

In operation S24, a first trip voltage may be set. Here, the first trip voltage may refer to the sensing trip voltage Vtrip_sensing, and the control circuit 260 of FIG. 2 may set the first trip voltage by applying the control voltage Vdyn to the gate of the trip control transistor PM_TC.

In operation S25, the switch transistor PM_SW may be turned on. For example, referring to FIG. 10, as the switch control signal CTRL_SW is activated at a low level during a predetermined period, the switch transistor PM_SW may be turned on.

Accordingly, in operation S26, a voltage Vso2 of the latch input node SO2 may be generated from the voltage Vso of the sensing node SO based on a trip voltage. In other words, based on a comparison between the developed voltage of the sensing node SO and the first trip voltage set in the operation S24, the voltage Vso2 of the latch input node SO2 may increase to the same level as the developed voltage of the sensing node SO or maintain the ground potential GND. Subsequently, in operation S27, a value corresponding to the voltage Vso2 of the latch input node SO2 may be latched into the latch circuit 221.

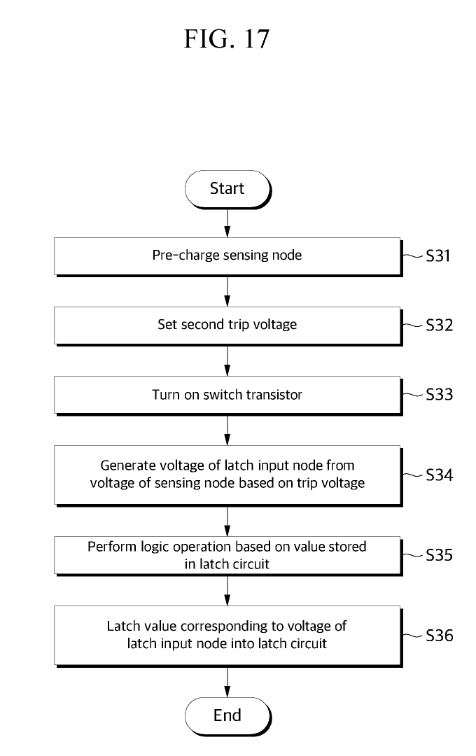

FIG. 17 is a flowchart illustrating a method of a dump operation of a memory device according to an example embodiment of the present disclosure. In some example embodiments, the method of FIG. 17 may be performed by the page buffer 220b of FIG. 10. As illustrated in FIG. 17, an operating method of the memory device may include a plurality of operations S31 to S36. Hereinafter, FIG. 17 will be described with reference to FIG. 10, and redundant details already provided in the descriptions of FIGS. 15 and 16 will be omitted.

Referring to FIG. 17, the sensing node SO may be pre-charged in operation S31, and a second trip voltage may be set in operation S32. Here, the second trip voltage may refer to the dump trip voltage Vtrip_dump, and the control circuit 260 of FIG. 2 may set the second trip voltage by applying the control voltage Vdyn to the gate of the trip control transistor PM_TC. At this point, the second trip voltage may be lower than the first trip voltage described above with reference to FIG. 16.

In operation S33, the switch transistor PM_SW may be turned on, and accordingly, in operation S34, the voltage Vso2 of the latch input node SO2 may be generated from the voltage Vso of the sensing node SO based on the second trip voltage. In other words, based on a comparison between the second trip voltage and the voltage Vso of the sensing node SO, the voltage Vso2 of the latch input node SO2 maybe generated at the same level as, for example, the voltage Vso of the sensing node SO.

In operation S35, a logic operation based on a value stored in the latch circuit 221 may be performed, and, for example, as the monitoring signal MON is activated, the seventh transistor NM7 is turned on, and the sensing node SO may be connected to another latch LT', for example, a force latch, an upper bit latch, or a lower bit latch, and at this point, the logic operation may be performed based on the value stored in the latch circuit 221. In one embodiment, in operation S35, a logic operation based on a value stored in the another latch LT’ may be performed. Subsequently, in operation S36, a value corresponding to the voltage Vso2 of the latch input node SO2 generated from a voltage of the sensing node SO may be latched into the latch circuit 221.

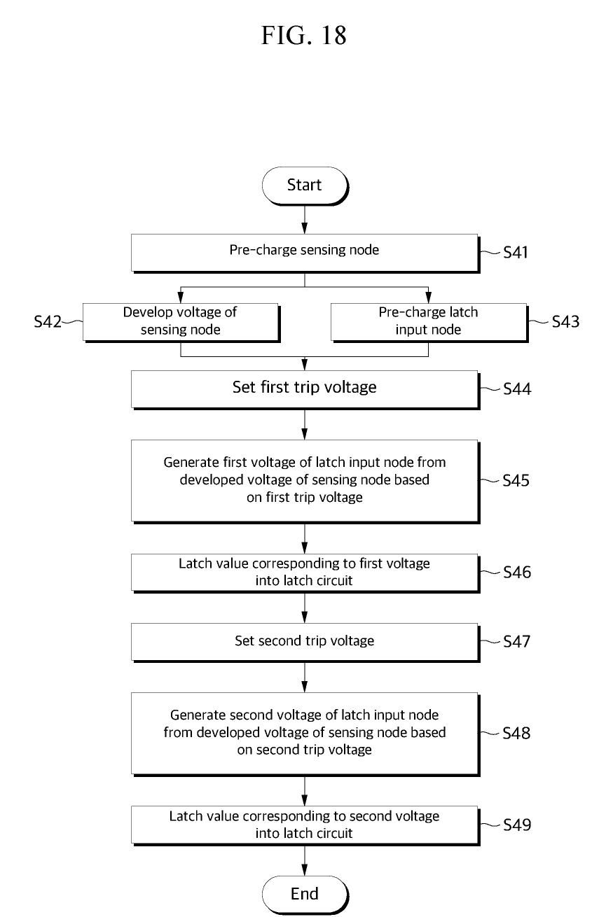

FIG. 18 is a flowchart illustrating an operating method of a memory device according to an example embodiment of the present disclosure. In some example embodiments, the method of FIG. 18 may be performed by the page buffer 220b illustrated in FIG. 10. As illustrated in FIG. 18, the operating method of the memory device may include a plurality of operations S41 to S49, and operation S42 may be performed in parallel with operation S43. Hereinafter, FIG. 18 will be described with reference to FIGS. 10 and 11A, and redundant details already provided in the descriptions of FIGS. 15 and 16 will be omitted.

Referring to FIG. 18, as described above with reference to FIG. 16, the sensing node SO may be pre-charged in operation S41, and a voltage Vso of the sensing node SO may be developed in operation S42, and the latch input node SO2 may be pre-charged in operation S43.

In operation S44, a first trip voltage may be set. Here, the first trip voltage may refer to the sensing trip voltage Vtrip_sensing to perform a first sensing, and the control circuit 260 of FIG. 2 may set the first trip voltage by applying the first target voltage Vdyn_target1 to the gate of the trip control transistor PM_TC.

In operation S45, a first voltage of the latch input node SO2 may be generated from a developed voltage of the sensing node SO based on the first trip voltage. In other words, the voltage Vso2 of the latch input node SO2 may increase to the same level as the developed voltage of the sensing node SO or maintain the ground potential GND based on a comparison between the developed voltage of the sensing node SO and the first trip voltage set in the operation S44. Subsequently, in operation S46, a value corresponding to the first voltage of the latch input node SO2 may be latched into the latch circuit 221.

In operation S47, a second trip voltage may be set. Here, the second trip voltage may refer to the sensing trip voltage Vtrip_sensing to perform a second sensing, and the control circuit 260 of FIG. 2 may set the second trip voltage by applying the second target voltage Vdyn_target2 to the gate of the trip control transistor PM_TC. At this point, the second target voltage Vdyn_target2 may be different from the first target voltage Vdyn_target1, and for example, may be higher or lower than the first target voltage Vdyn_target1. In addition, in some example embodiments, pre-charge of the latch input node SO2 may be simultaneously performed in parallel with setting the second trip voltage.

In operation S48, a second voltage of the latch input node SO2 may be generated from the developed voltage of the sensing node SO based on the second trip voltage. In other words, the voltage Vso2 of the latch input node SO2 may increase to the same level as the developed voltage of the sensing node SO or maintain the ground potential GND based on a comparison between the developed voltage of the sensing node SO and the second trip voltage set in the operation S47. Subsequently, in operation S49, a value corresponding to the second voltage of the latch input node SO2 may be latched into the latch circuit 221.

Based on the method of FIG. 18 described above, the memory device of the present disclosure may perform multi-sensing by differently setting the sensing trip voltage Vtrip_sensing corresponding to each sensing operation after developing the sensing node SO one time. Therefore, the memory device of the present disclosure may provide the same effect as performing multi-sensing while varying a wordline voltage and also provide an effect of reducing read time in that the memory device performs multi-sensing with only one-time sensing node pre-charge and development.

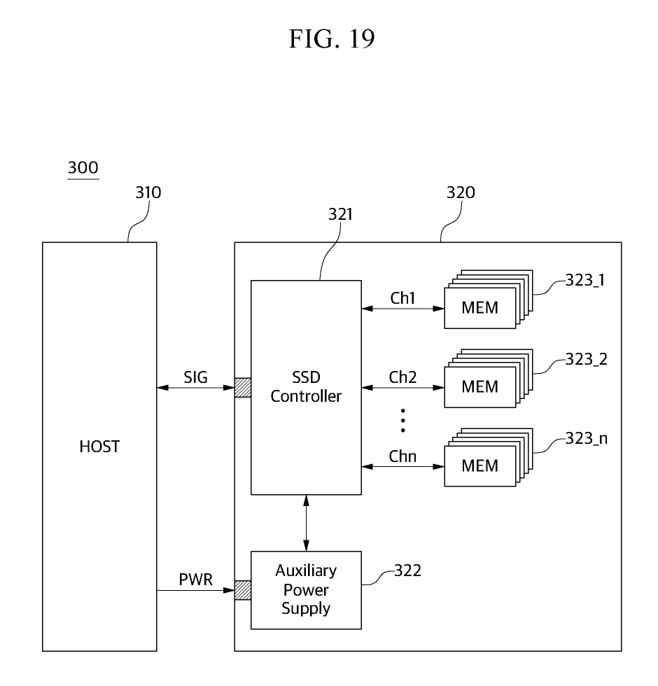

FIG. 19 is a block diagram illustrating a memory system 300 according to example embodiments of the present disclosure. A solid state drive (SSD) 320 in the memory system 300 may include the memory device described above with reference to the diagrams.

Referring to FIG. 19, the memory system 300 may include a host 310 and an SSD 320. The SSD 320 may exchange a signal SIG with the host 310 through a signal connector and may be inputted a power PWR through a power connector. The SSD 320 may include an SSD controller 321, an auxiliary power supply 322, and memory devices 323_1 to 323_n, and in some example embodiments, the memory devices 323_1 to 323_n may be a vertically stacked NAND flash memory device.

The memory devices 323_1 to 323_n of FIG. 19 may include the memory device described above with reference to FIGS. 1 to 18. For example, each of the memory devices 323_1 to 323_n may be configured to set a different trip voltage based on a mode of a page buffer and to perform multi-sensing by varying a trip voltage multiple times after one-time sensing node development.

While the inventive concept has been particularly shown and described with reference to embodiments thereof, it will be understood that various changes in form and details may be made therein without departing from the spirit and scope of the present invention as set forth in the following claims.

What is claimed is:

1. An operating method of a memory device including a memory cell array and a page buffer connected to the memory cell array through a plurality of bitlines, the operating method comprising:
pre-charging a sensing node of a sensing circuit of the page buffer connected to a first bitline among the plurality of bitlines;
setting a trip voltage based on a mode of the page buffer;
generating a voltage of a latch input node connected between the sensing circuit and a latch circuit of the page buffer from a voltage of the sensing node based on the trip voltage; and
latching a value corresponding to the voltage of the latch input node into the latch circuit.

2. The operating method of claim 1, wherein the setting of the trip voltage comprises:
setting a first trip voltage in a first mode of the page buffer; and
setting a second trip voltage different from the first trip voltage in a second mode of the page buffer.

3. The operating method of claim 2, further comprising:
in the first mode, developing the voltage of the sensing node that is pre-charged based on a cell current flowing through the first bitline; and
in the second mode, performing a logic operation based on a value stored in the latch circuit.

4. The operating method of claim 3, wherein the first trip voltage is higher than the second trip voltage.

5. The operating method of claim 3, further comprising:
in the first mode, turning-off a transistor connected between the sensing node and the latch input node while the voltage of the sensing node is developed; and
in the first mode, turning-on the transistor after the voltage of the sensing node is developed.

6. The operating method of claim 5, further comprising:
turning-on the transistor in the second mode.

7. The operating method of claim 3, further comprising:
pre-charging the latch input node in the first mode.

8. The operating method of claim 1, wherein the setting of the trip voltage comprises:
identifying a trip voltage corresponding to the mode; and
based on the trip voltage that is identified, applying a voltage to a gate of a transistor connected between the sensing node and the latch input node.

9. The operating method of claim 1, wherein the setting of the trip voltage comprises:
selectively supplying power to an inverter pair included in the latch circuit based on the mode.

10. A memory device, comprising:
a memory cell array including a plurality of memory cells;
a page buffer connected to the memory cell array through a plurality of bitlines; and
a control circuit configured to control the page buffer,
wherein the page buffer comprises:
a sensing circuit configured to generate a voltage of a latch input node from a voltage of a sensing node based on a trip voltage; and
a latch circuit configured to latch a value corresponding to the voltage of the latch input node,
wherein the control circuit is configured to set the trip voltage based on a mode of the page buffer.

11. The memory device of claim 10, wherein the control circuit is configured to:
set a first trip voltage in a first mode of the page buffer, and
set a second trip voltage different from the first trip voltage in a second mode of the page buffer.

12. The memory device of claim 11, wherein the sensing circuit is configured to:
develop the voltage of the sensing node pre-charged in the first mode depending on a cell current flowing through a selected bitline among the plurality of bitlines, and
perform a logic operation based on a value stored in the latch circuit in the second mode.

13. The memory device of claim 12, wherein the first trip voltage is higher than the second trip voltage.

14. The memory device of claim 12,
wherein the sensing circuit includes a transistor connected between the sensing node and the latch input node, and
wherein, in the first mode, the control circuit is configured to:
turn off the transistor while the voltage of the sensing node is developed, and
turn on the transistor after the voltage of the sensing node is developed.

15. The memory device of claim 14, wherein the control circuit is configured to turn on the transistor in the second mode.

16. The memory device of claim 12, wherein the control circuit is configured to pre-charge the latch input node in the first mode.

17. The memory device of claim 10,
wherein the sensing circuit includes a transistor connected between the sensing node and the latch input node, and
wherein the control circuit is configured to:
identify a trip voltage corresponding to the mode, and
apply a voltage to a gate of the transistor based on the trip voltage that is identified.

18. An operating method of a memory device including a memory cell array and a page buffer connected to the memory cell array through a plurality of bitlines, the operating method comprising:
pre-charging a sensing node of a sensing circuit of the page buffer connected to a first bitline among the plurality of bitlines;
developing a voltage of the sensing node based on a cell current flowing through the first bitline;
setting a first trip voltage;
generating a first voltage of a latch input node from the voltage of the sensing node developed based on the first trip voltage;
latching a value corresponding to the first voltage into a latch circuit of the page buffer;
setting a second trip voltage different from the first trip voltage;
generating a second voltage of the latch input node from the voltage of the sensing node developed based on the second trip voltage; and
latching a value corresponding to the second voltage into the latch circuit.

19. The operating method of claim 18, further comprising:
pre-charging the latch input node before the generating of the first voltage,.

20. The operating method of claim 19, further comprising:
pre-charging the latch input node before the generating of the second voltage.
